(19) United States
(12) Patent Application Publication
(10) Pub. No.: US 2026/0371610 A1
(43) Pub. Date: Nov. 19, 2026

(54) SEMICONDUCTOR DEVICE AND METHOD FOR FABRICATING THE SAME

(71) Applicant: SK hynix Inc., Gyeonggi-do (KR)

(72) Inventor: Cha Deok DONG, Gyeonggi-do (KR)

(21) Appl. No.: 19/403,010

(22) Filed: Nov. 27, 2025

(30) Foreign Application Priority Data
May 19, 2025 (KR) 10-2025-0064388

(51) Int. Cl. H10B 63/00; H10N 70/00

(52) U.S. Cl. CPC H10B 63/20; H10N 70/021; H10N 70/826; H10N 70/841

(57) ABSTRACT

A semiconductor device and a method for making the same, the semiconductor device including a first conductive line pattern having a conductive thin layer with a thickness of 10 nm to 30 nm disposed thereon, a lower electrode layer formed over the first conductive line pattern, and a selector layer formed over the lower electrode layer, wherein the conductive thin layer and the lower electrode layer are formed of the same material.

### CROSS-REFERENCE TO RELATED APPLICATIONS

The present application claims priority under 35 U.S. C 119(a) to Korean Patent Application No. 10-2025-0064388, filed on May 19, 2025, which is incorporated herein by reference in its entirety.

### BACKGROUND

### 1. Field

Embodiments of the present disclosure relate to a semiconductor technology, and more particularly, to a semiconductor device including a selector, and a method for fabricating the semiconductor device.

### 2. Description of the Related Art

Recent demands for miniaturization, low power consumption, high performance, and diversification of electronic devices have created a need for semiconductor devices capable of storing data in diverse electronic devices, such as computers, portable communication devices, and the like, and researchers and the industry are actively working to develop such semiconductor devices. The semiconductor devices include those capable of storing data by using the characteristics of switching between different resistance states according to the applied voltage or current, such as Resistive Random Access Memory (RRAM), Phase-change Random Access Memory (PRAM), Ferroelectric Random Access Memory (FRAM), Magnetoresistive Random Access Memory (MRAM), E-fuse, and the like. However, further improvements are needed.

### SUMMARY

Various embodiments of the present disclosure are directed to a semiconductor device that forms a selector layer of a uniform thickness. These embodiments aim to improve the reliability of Storage Class Magnetoresistive Random Access Memory (SC-MRAM) by proposing a new process for achieving surface flatness. This process addresses the problem of lower step height differences that may arise during the fabrication of highly integrated SC-MRAM devices. The disclosure also includes a method for fabricating the semiconductor device.

In accordance with an embodiment of the present disclosure, a semiconductor device includes a first conductive line pattern having a conductive thin layer with a thickness of 10 nm to 30 nm deposited thereon; a lower electrode layer formed over the first conductive line pattern; and a selector layer formed over the lower electrode layer, wherein the conductive thin layer and the lower electrode layer are formed of a same material.

In accordance with another embodiment of the present disclosure, a method includes forming a conductive thin layer over a first conductive line; forming a plurality of first conductive line patterns by patterning the first conductive line over which the conductive thin layer is formed; forming an oxide gap-fill layer between the first conductive line patterns; forming a lower electrode layer over the first conductive line patterns and the oxide gap-fill layer; and planarizing an upper surface of the lower electrode layer, wherein the conductive thin layer and the lower electrode layer are formed of a same material.

In accordance with an embodiment of the present disclosure, a semiconductor device includes a plurality of first conductive line patterns disposed over a substrate; an oxide gap-fill layer between the first conductive line patterns; a conductive thin layer having a thickness of 10 nm to 30 nm and being disposed on the first conductive line patterns; a lower electrode layer formed over the first conductive line patterns and the oxide gap-fill layer; and a selector layer formed over the lower electrode layer, wherein the conductive thin layer and the lower electrode layer are formed of a same material.

These and other features and advantages of the embodiments of the present disclosure will become apparent to those skilled in the art from the following detailed description in conjunction with the following drawings.

### BRIEF DESCRIPTION OF THE DRAWINGS

FIGS. 1A to 1G illustrate a semiconductor device and a method for fabricating the same according to a comparative example.

FIGS. 2A to 2F illustrate a semiconductor device and a method for fabricating the same in accordance with an embodiment of the present disclosure.

FIGS. 3A to 3C illustrate a semiconductor device and a method for fabricating the same in accordance with another embodiment of the present disclosure.

### DETAILED DESCRIPTION

Hereinafter, various embodiments of the present disclosure will be described in detail with reference to the accompanying drawings. It is noted, however, that the embodiments of the present disclosure may be embodied in different other forms and should not be construed as limited to the embodiments set forth herein. Rather, these embodiments are provided so that the present disclosure is thorough and complete, and fully conveys the scope of the present disclosure to those with ordinary skill in the art. Throughout this disclosure, like reference numerals refer to like parts throughout the various figures and embodiments of the present disclosure.

The drawings are not necessarily to scale and in some instances, proportions may have been exaggerated to clearly illustrate features of the embodiments. When a first layer is referred to as being ‘on’ a second layer or ‘on’ a substrate, it not only refers to a case where the first layer is formed directly on the second layer or the substrate but also a case where a third layer exists between the first layer and the second layer or the substrate.

The embodiments of the present disclosure relate to a method for fabricating a highly integrated Storage Class Magnetoresistive Random Access Memory (SC-MRAM) device, and more particularly, to a technique for mitigating or preventing a problem that may occur in a process of forming a step height and a cell patterning process by optimizing the thickness of a lower electrode layer that is formed in the upper portion of a first conductive line which corresponds to a word line.

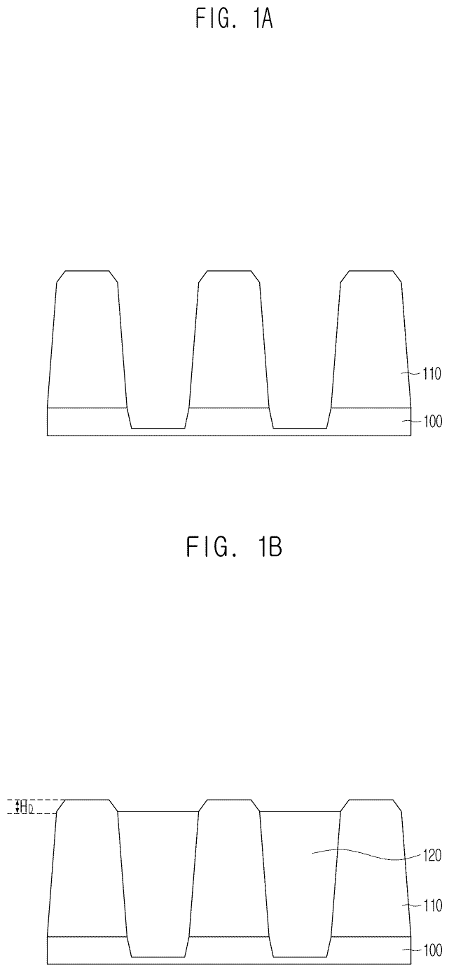

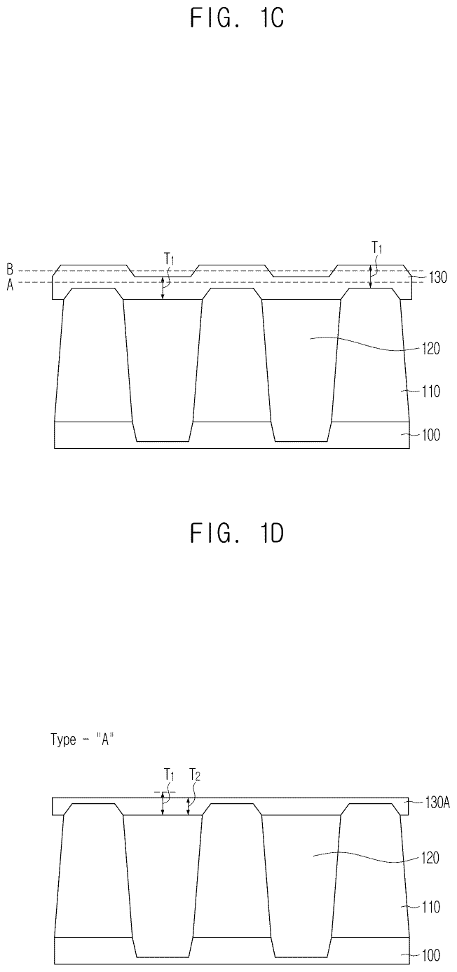

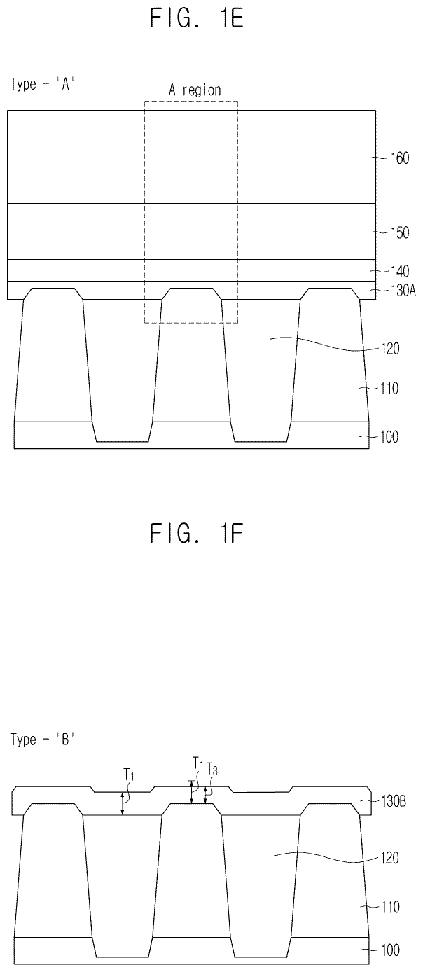

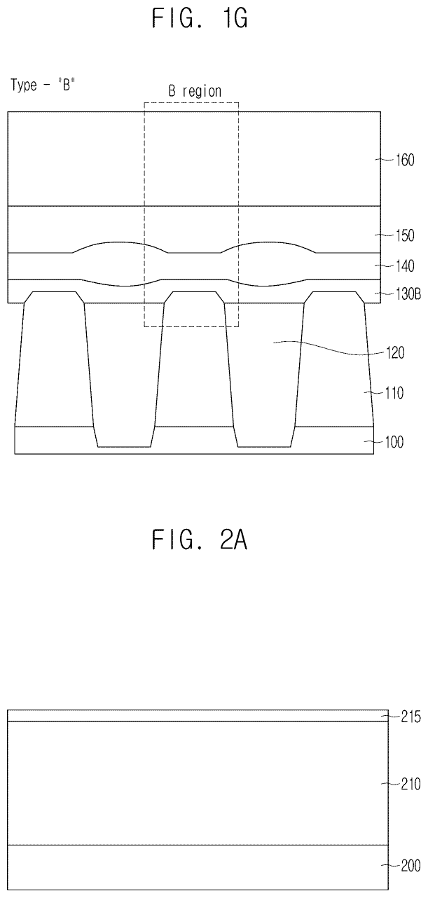

Before describing the semiconductor device in accordance with the embodiment of the present disclosure, to more clearly reveal the stacked structure of a first conductive line and a selector layer in accordance with the embodiment of the present disclosure and the effect resulting from the stacked structure, a semiconductor device according to a comparative example will be described first. FIGS. 1A to 1G illustrate a semiconductor device and a method for fabricating the same according to a comparative example.

Referring to FIGS. 1A and 1B, a general semiconductor device according to the comparative example may be fabricated by forming a plurality of first conductive line patterns 110 over a substrate 100 and forming an oxide gap-fill layer 120 between the first conductive line patterns 110. The first conductive line patterns 110 may be formed of a material such as molybdenum (Mo), ruthenium (Ru), cobalt (Co), or tungsten (W). However, in the process of forming the first conductive line patterns 110, the upper portions of the first conductive line patterns 110 may have a tapered shape, which may cause a problem of an uneven upper profile.

Referring to FIG. 1B, after an oxide gap-fill layer 120 is formed for insulation between the first conductive line patterns 110, a process of planarizing the upper surfaces of the first conductive line patterns 110 and the oxide gap-fill layer 120 may be performed. However, even though a planarization process such as Chemical Mechanical Polishing (CMP) is applied, the upper portion of the oxide gap-fill layer 120 may not be disposed at the same height as the height of the first conductive line patterns 110, and accordingly a step height of a predetermined height HD may be usually generated. This step height may affect the subsequent process, and to solve this problem, a method of adjusting the heights of the first conductive line patterns 110 and the oxide gap-fill layer 120 by precisely controlling the CMP process may be considered. However, during this process, a problem of an oxide thin layer remaining in the upper portions of the first conductive line patterns 110 may occur. Also, a problem that the step height increases further may arise in the process of removing the oxide thin layer in the cleaning process prior to the deposition of the lower electrode layer 130 that is performed subsequently.

Referring to FIG. 1C, since the lower electrode layer 130 is deposited with a predetermined thickness T₁ from the upper surfaces of the first conductive line patterns 110 and the oxide gap-fill layer 120, the surface step height between the first conductive line patterns 110 and the oxide gap-fill layer 120 may be maintained even after the lower electrode layer 130 is deposited. However, to form the selector layer 140 over the lower electrode layer 130, a planar electrode layer may be required. To this end, it is important to select a material for the lower electrode layer 130. As for the material of the lower electrode layer 130, titanium nitride (TiN), molybdenum (Mo), tungsten (W), ruthenium (Ru), or tantalum nitride (TaN) may be used. An additional CMP process is therefore required to remove the step height after the deposition of the lower electrode layer 130. However, when the CMP is performed excessively, the thickness of the lower electrode layer 130 may be excessively reduced or the surface of the lower electrode 130 may become nonuniform. Therefore, it is important to appropriately control the deposition thickness of the lower electrode layer 130.

As a result, the final shape of the lower electrode layer 130 after the CMP process may be generally divided into Type A and Type B. When the lower electrode layer 130 is formed excessively thick, the amount of the lower electrode layer 130 that needs to be removed in the subsequent cell patterning process may be increased, which increases the possibility of a bridge to be formed between the first conductive line patterns 110. Also, when a byproduct is deposited on the sidewall of the selector layer 140, a leakage current may increase, deteriorating the reliability of the device. Therefore, it is important to minimize the step height that may be formed based on the thickness of the lower electrode layer 130, and generally, a CMP process of type A may be preferred.

FIGS. 1D and 1E illustrate an embodiment in which a CMP process of type A is performed up to a line A of FIG. 1C.

Referring to FIG. 1D, the lower electrode layer 130 may be planarized up to the line A of FIG. 1C by the CMP process of type A, and the thickness of the lower electrode layer 130 may be reduced from T₁ to T₂. As a result, a planar lower electrode layer 130A may be formed.

Referring to FIG. 1E, a planar surface may be secured through the CMP process of type A, and through the process, a foundation for uniformly forming the selector layer 140 may be established. Since the CMP process may remove the surface nonuniformity and provide a planar surface, it is possible to obtain a uniform thickness and structure in the subsequent process for forming the selector layer 140. When the first intermediate electrode layer 150 and the second intermediate electrode layer 160 are sequentially deposited on the planarized surface, the uniformity of the thickness and electrical characteristics of the selector layer 140 may be maintained. As a result, a cell pattern represented by an ‘A region’ may be formed, and the characteristics of the entire selector layer 140 may be maintained uniformly.

However, when using this conventional process, a problem may occur in that the thickness of the lower electrode layer 130A remaining on the upper portion of the first conductive line patterns 110 becomes very thin. When the thickness of the lower electrode layer 130A is not sufficiently secured, the electrical characteristics may become nonuniform at the joint portion between the first conductive line patterns 110 and the selector layer 140 when the selector layer 140 is formed. In particular, when the thickness of the lower electrode layer 130A is too thin, the electrical characteristics of the selector layer 140 may deteriorate, or nonuniform conduction characteristics may appear when the selector layer 140 is formed. Such nonuniformity may cause deterioration in electrical performance in the inside of the selector layer 140 and may affect the operation of a memory cell.

Therefore, it is important to maintain the thickness of the lower electrode layer 130A at an appropriate level and manage the thickness not to become too thin. This may make it possible to optimize the electrical characteristics of the selector layer 140 and prevent the formation of a nonuniform selector layer. Managing the characteristics of the selector layer 140 not to be deteriorated may be important to secure the performance and reliability of an SC-MRAM memory cell, and in the long term, it may also contribute to improving the production yield.

The lower electrode layer 130A may have to be secured with a sufficient thickness. In the process of forming the selector layer 140, an ion implantation process may be used to uniformly implant an impurity, such as arsenic (As), into a silicon oxide (SiO₂) thin layer, and appropriate acceleration voltage Vacc and energy may be essential in this process. The process of implanting arsenic (As) ions may affect up to the lower electrode layer 130A. Even in the arsenic (As) ion implantation process which is set to an appropriate level of energy, when the lower electrode layer 130A is thin, there may be a problem in that arsenic (As) may penetrate even into the first conductive line patterns 110, and as a result, an effect of scattering the material of the first conductive line patterns 110, for example, tungsten (W), may occur, and the penetration into the selector layer 140 may not be controlled. Also, even when the thickness of the silicon oxide is adjusted to be thin to lower a cell switching voltage Vf and Vth, the scattering problem of the material of the first conductive line patterns 110, such as tungsten (W), may persist when the thickness of the lower electrode layer 130A is thin. This problem may occur due to the structural characteristics of forming the selector layer 140 in the upper portion of the first conductive line patterns 110 and may act as an unfavorable factor in terms of the process margin. Furthermore, this problem may become more serious when the thicknesses of both of the lower electrode layer 130A and the silicon oxide are thin. Therefore, securing the lower electrode layer 130A of a sufficient thickness may be essential for preparing for diverse process variables.

FIGS. 1F and 1G illustrate an embodiment in which a CMP process of type B is performed up to a B line of FIG. 1C.

Referring to FIG. 1F, the lower electrode layer 130 may be planarized up to the B line of FIG. 1C through the CMP process of type B, and the thickness of the lower electrode layer 130 over the first conductive line patterns 110 may be decreased from T₁ to T₃, but the thickness of the lower electrode layer 130 over the oxide gap-fill layer 120 may remain unchanged at T₁. Accordingly, the formed lower electrode layer 130B may maintain a sufficient thickness, but since the planarization is not perfectly achieved, there is a possibility that a micro-dishing phenomenon may continue. Also, since the thickness of the lower electrode layer 130B that may have to be removed during a cell patterning process is not different from the initial deposition thickness, the process efficiency may be decreased.

Referring to FIG. 1G, when a thick lower electrode layer 130B remains in the upper portion of the first conductive line patterns 110 in the CMP process of type B, the micro-dishing phenomenon may continue. This phenomenon becomes more prominent during the silicon oxide deposition process and the arsenic (As) ion implantation process when the selector layer 140 is formed. As arsenic (As) ions are scattered to the thick portion in the upper portion of the lower electrode layer 130B, the upper portion of the selector layer 140 may become thicker than expected or may be formed nonuniformly. This may cause the thickness and electrical characteristics of the selector layer 140 to become nonuniform, which may deteriorate the performance of the selector layer 140.

When the cell patterning process is performed, a cell pattern represented by a ‘B region’ may be formed, and a cell in which the edges of the formed selected pattern are thick may be formed, which is a problem. This is because, due to the nonuniform formation of the selector layer 140, the thick portion of the lower electrode layer 130B may affect the process of forming the selector layer 140, causing a difference in the characteristics of the selector layer 140. Also, this phenomenon may cause an electrical resistance difference in the selector layer 140 and make the operation of the memory cell unstable.

Therefore, it is important to manage the thickness of the lower electrode layer 130B not to be too thick, and the micro-dishing may have to be minimized and the selector layer 140 may have to be formed uniformly. Through this process, it is possible to maintain the electrical characteristics of the selector layer 140 uniformly and to prevent nonuniformity during the formation of the selector layer 140. When the thickness of the lower electrode layer 130B is not managed, the characteristics of the selector layer 140 may be deteriorated, which may have a negative effect on the overall performance of the SC-MRAM device.

Also, the nonuniform thickness of the selector layer 140 may be more clearly revealed according to the shape of the first intermediate electrode layer 150 which is formed in the upper portion of the selector layer 140. Therefore, when the thickness of the lower electrode layer 130B is formed excessively thick, an additional problem may occur during the cell patterning process.

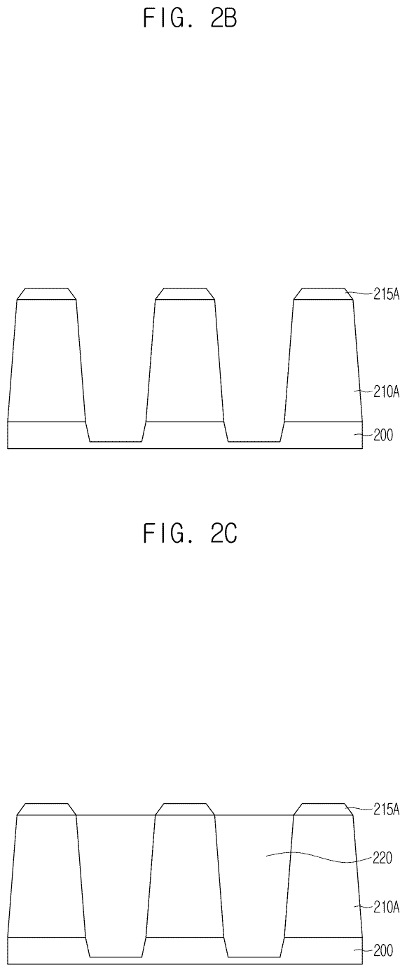

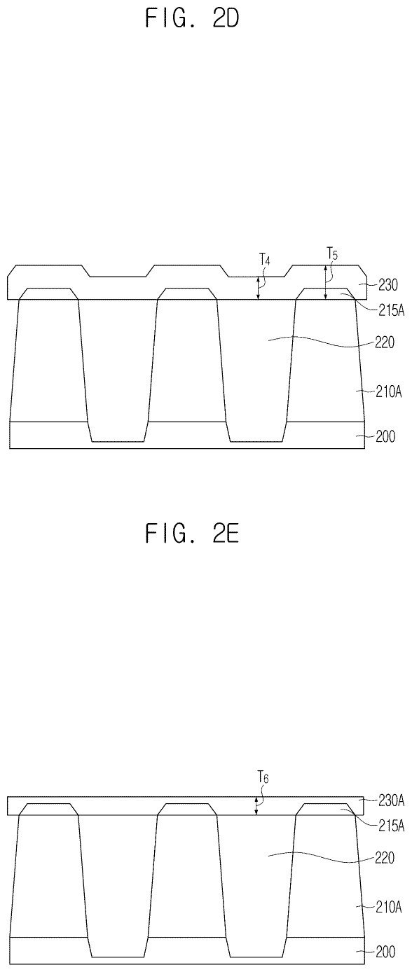

For solving the problem of the semiconductor device of this comparative example, embodiments of the present disclosure provide a semiconductor device and a method for fabricating the same that form a conductive thin layer including the same material as that of the lower electrode layer 130 over the first conductive line patterns 110 which prevents deterioration of the selector layer by effectively controlling the scattering of the material included in the first conductive line patterns 110 during the formation of the selector layer, and at the same time, ensures uniform cells by forming the selector layer to have a uniform thickness. In this way, the performance and production yield of the SC-MRAM is improved. This embodiment is described below with reference to FIGS. 2A to 2F.

Referring to FIG. 2A, a first conductive line 210 may be formed over a substrate 200, and a conductive thin layer 215 may be formed over the first conductive line 210.

The substrate 200 may be a structure that serves as the basis of a semiconductor device. The substrate 200 may be formed of silicon (Si) or other semiconductor materials. A dielectric layer or a buffer layer may be added if necessary. Diverse lower structures may be formed in the substrate 200 by using fine processing techniques, for example, devices such as a transistor, a diode, a capacitor and the like, may be integrated, and a contact plug or a via structure for electrical connection with a wiring layer including the first conductive line 210 may also be included.

The first conductive line 210 may be a word line WL. The first conductive line 210 may function to transfer a selection signal in a memory cell array, and may be used as an electrode for transferring a signal, supplying power, or processing data. According to a specific application, it may be formed as a single-layer structure or a multi-layer structure using diverse conductive materials, and it may be generally formed of a metal or a metal nitride with a low resistance and a high reliability. For example, the electrical characteristics of the first conductive line 210 may be optimized by using a conductive material, such as titanium nitride (TiN), tungsten (W), tantalum nitride (TaN), copper (Cu) and the like.

The first conductive line 210 may be formed by forming a dielectric layer (not shown) including a trench formed in the substrate 200, depositing a conductive layer in the trench, and patterning and etching the dielectric layer. The conductive layer may be mainly deposited by a method such as sputtering, chemical vapor deposition (CVD), or atomic layer deposition (ALD), and diverse conductive materials may be applied to lower the resistance of the word line and improve the signal transfer characteristics.

After the first conductive line 210 is formed, a planarization process may be performed to secure surface uniformity and to improve the reliability in a subsequent process. An etch-back method or a chemical mechanical polishing (CMP) method may be used as the planarization process, and through this planarization process, the upper surface of the first conductive line 210 may be cleaned to secure a stable structure in the subsequent processes of forming a dielectric layer and stacking an additional element. Also, to optimize the characteristics of the various parts of the semiconductor device, such as a lower electrode layer 230 and a selector layer 240, which are to be formed over the first conductive line 210, it is important to minimize the roughness of the surface of the first conductive line 210 and to secure a uniform thickness when forming the first conductive line 210. The conductive thin layer 215 may be formed over the first conductive line 210. The conductive thin layer 215 may be formed of a same material as that of the lower electrode layer 230 so that the conductive thin layer 215 may be integrated with the lower electrode layer 230 in a subsequent process. This conductive thin layer 215 may contribute to forming the lower electrode layer 230 uniformly and minimize the contact resistance. The conductive thin layer 215 may be formed of the same material as that of the lower electrode layer 230 described below, and may include one or more selected from the group including C, CN, SiO₂, Si₃N₄, HfO₂, Al₂O₃, TiO₂, Ti, TiN, TiAlN, W, WN, Ta, TaN, Ru, RuO₂, Mo, MoN, Ir, and Pt. The conductive thin layer 215 may be deposited as a single material or in a combined form as needed. This process may make it possible to form a uniform surface in a subsequent process while maintaining material consistency with the lower electrode layer 230.

In particular, since noble metal-based materials, such as ruthenium (Ru), iridium (Ir), platinum (Pt) and the like, have excellent conductivity and excellent oxidation resistance and heat resistance, they may be usefully used as the lower electrode layer of a memory device or a high-performance semiconductor device. Also, since metal nitrides such as TaN or TiN have excellent oxidation resistance and high durability, they may be frequently used in a high-reliability semiconductor fabrication process.

Processes such as chemical vapor deposition (CVD), physical vapor deposition (PVD), and atomic layer deposition (ALD) may be used as a method for forming the conductive thin layer 215, and the optimal electrical characteristics may be acquired by controlling the thickness and composition to desired levels. The conductive thin layer 215 may be formed to have a thickness equal to or greater than the step height between the first conductive line patterns 210A and the oxide gap-fill layer 220, to secure a more uniform shape in a subsequent process.

Referring to FIGS. 2B and 2C, the first conductive line 210 and the conductive thin layer 215 may be patterned to form first conductive line patterns 210A and conductive thin layer patterns 215A. Since the conductive thin layer pattern 215A is formed on the upper portions of the formed first conductive line patterns 210A, the upper portions of the first conductive line patterns 210A may not be recessed, and only the conductive thin layer patterns 215A may be recessed to have a tapered shape. This may contribute to improving the bonding characteristics with an oxide gap-fill layer 220 in the subsequent process.

Subsequently, an oxide gap-fill layer 220 may be formed by gap-filling an oxide between the first conductive line patterns 210A. The oxide gap-fill layer 220 may serve to fill the space between the first conductive line patterns 210A, and this layer may contribute to stabilizing the overall physical structure of the device and improving the electrical characteristics. The oxide gap-fill layer 220 may include one or more selected from the group including silicon oxide, aluminum oxide, zirconium oxide, hafnium oxide, tantalum oxide, magnesium oxide, and yttrium oxide.

For example, silicon oxide (SiO₂) may be widely used due to its excellent dielectric characteristics, and hafnium oxide (HfO₂) or zirconium oxide (ZrO₂) may provide a high dielectric constant and excellent heat resistance to maintain stability even in a high-temperature environment. Also, aluminum oxide (Al₂O₃) may provide high chemical resistance and mechanical strength, which may contribute to an increase of the durability of the device. Each oxide may not only provide electrical insulation, but also block the diffusion of an impurity that may occur during the process.

It is important to improve the gap-fill characteristics and minimize the generation of pores during the process of forming the oxide gap-fill layer 220. To this end, the High-Density Plasma (HDP) chemical vapor deposition (CVD) process may enable more uniform deposition by using high-density plasma and form a high-density oxide layer by minimizing pores. Also, a spin on dielectric (SOD) deposition process may be a method of forming a dielectric layer of a uniform thickness as an organic solution applied in a liquid state evaporates. The spin-on-dielectric (SOD) deposition process may make it possible to precisely fill the oxide gap-fill layer 220. A flowable oxide process may be able to fill finer gaps with a highly flowable oxide and minimize pores and defects by performing an appropriate curing process and a heat treatment after the process.

Therefore, the oxide gap-fill layer 220 may improve the performance of a device, minimize the defects that may occur during the process, and contribute to ensuring the uniformity of the final device. This may optimize the electrical performance and enhance the stability of the device further.

The same profile as before may be secured as a planarization process is performed based on the upper portions of the first conductive line patterns 210A by performing a chemical mechanical polishing (CMP) process after the oxide gap-fill layer 220 is formed. However, even after the CMP process, a step height as much as the height of the tapered conductive thin layer patterns 215A may still remain in the upper portions of the first conductive line patterns 210A. This step height may deteriorate the uniformity in the subsequent processes of forming a dielectric layer and stacking additional elements and may particularly affect the reliability of a memory device, such as a variable resistance random access memory, e.g., a Resistive Random Access Memory (RRAM). Therefore, it is possible to further alleviate the surface step height and improve the degree of precision of the subsequent process by applying an additional reflow process, an annealing process, or an auxiliary CMP process as needed.

Referring to FIG. 2D, a lower electrode layer 230 may be formed over the first conductive line patterns 210A and the oxide gap-fill layer 220. The lower electrode layer 230 may be uniformly deposited in a predetermined thickness T₄. However, since a step height corresponding to the thickness T₅-T₄ of the existing conductive thin film pattern 215A remains on top of the first conductive line pattern 210A, the lower electrode layer 230 is formed with a total thickness of T₅ on the first conductive line pattern 210A. Accordingly, a step height of T₅-T₄ is still maintained between the top surfaces of the first conductive line pattern 210A and the oxide gap-fill layer 220.

This step height may affect the deposition uniformity and patterning precision in subsequent processes, and may cause structural nonuniformity, particularly when an upper element is formed. Therefore, it may be required to perform a pre-cleaning process to improve the bonding resistance before the lower electrode layer 230 is deposited. This is because variations in topography can lead to irregular film coverage and defects in alignment, ultimately compromising device performance and yield. During the pre-cleaning process, the bonding resistance between the lower electrode layer 230 and the underlying structure may be minimized by activating the surface through a plasma treatment using, for example, argon (Ar) plasma or hydrogen (H₂) plasma, or by removing a native oxide layer through a wet cleaning process using, for example, a hydrogen fluoride (HF)-based solution.

When the lower electrode layer 230 is deposited after the pre-cleaning process, the lower electrode layer may be formed with the step height maintained as illustrated in the structure of FIG. 2D. The step height may be further alleviated by performing an additional planarization process, for example, a CMP process, and if necessary, the uniformity in the subsequent process may be improved by adjusting the thickness of the lower electrode layer 230. These processes may make it possible to optimize the electrical characteristics of the lower electrode layer and secure the process margin in the subsequent process.

Even though the CMP process of the lower electrode layer 230 is managed at the same level as that of the existing CMP process by depositing the lower electrode layer 230 after performing a cleaning process of removing only the native oxide layer, the thickness of the conductive thin layer 215A which is formed of the same material as that of the lower electrode layer 230 which is already formed in the upper portion of the first conductive line patterns 210A is sufficiently secured. Therefore, it is possible to prevent scattering and surface damage of the metal material of the first conductive line patterns 210A, such as tungsten (W), that may be caused due to the ion implantation of arsenic (As) during the process of forming the selector layer 240.

The arsenic (As) ion implantation process may be performed during the formation of the selector layer 240. When the first conductive line patterns 210A are directly exposed during the arsenic (As) ion implantation process, a metal such as tungsten (W) may react with the arsenic (As), resulting in unexpected interface deformation or contamination. Also, there is a possibility that a nonuniform interface may be formed as the metal atoms are released to the surface or rearranged due to the arsenic (As) ion implantation. Arsenic (As) ion implantation may induce the diffusion or redistribution of metal atoms toward the surface, which can lead to the formation of an irregular interface layer—potentially compromising interfacial stability and subsequent process integration. This phenomenon may deteriorate the electrical characteristics of the selector layer 240, and in particular, problems such as a change in the resistance or increased leakage current may occur.

However, when the conductive thin layer 215A is secured with sufficient thickness, it can effectively shield the underlying metal surface of the first conductive line patterns 210A from direct exposure during the ion implantation process. The metal surface of the first conductive line patterns 210A is not directly exposed during the ion implantation process. In doing so, the conductive thin layer 215A serves as a protective layer, allowing the ion implantation process to be performed more uniformly. This makes it possible to stably maintain the characteristics of the selector layer 240, suppressing the formation of an abnormal selector layer 240, and thereby ensuring the uniformity of the entire memory cells. For example, the conductive thin layer 215A may have a thickness of approximately 10 nm to approximately 30 nm. By setting the thickness of the conductive thin layer 215A to approximately 10 nm to approximately 30 nm, it is possible to prevent the metal surface from being directly exposed during the arsenic (As) ion implantation process, and at the same time, help the ion implantation to be performed uniformly. When the thickness of the conductive thin layer 215A is maintained at the appropriate level, the metal of the first conductive line pattern 210A may not be exposed during the arsenic (Ar) ion implantation. Therefore, it is possible to prevent an unnecessary reaction or interface deformation between the arsenic (Ar) and the metal. The function as a protective layer may effectively solve the problems that may occur during the process of forming the selector layer 240, such as deterioration in the electrical characteristics or formation of a nonuniform interface.

Also, the electrical characteristics of the conductive thin layer 215A may be optimized by setting the thickness of the conductive thin layer 215A to a range of approximately 10 nm to 30 nm. A conductive thin layer that is too thick may have a negative effect on the electrical characteristics, and a conductive layer that is too thin may not sufficiently function as a protective layer. A thickness of approximately 10 nm to 30 nm may be considered an ideal thickness range for providing a protective layer which is sufficiently strong while maintaining the electrical characteristics required during the formation of the selector layer 240. Furthermore, this thickness range may also make the conductive thin layer 215A deposited uniformly. Whereas when the thickness is too thick, it is difficult to maintain the uniformity during the deposition process, the thickness range of approximately 10 nm to 30 nm may make it possible to secure the physical characteristics required for the fabrication process while maintaining the uniform characteristics.

Also, since the conductive thin layer 215A is formed to have a sufficient thickness, it may also contribute to maintaining the CMP uniformity during the subsequent process. When over-polishing occurs in a predetermined region during the CMP process, the thickness uniformity of the lower electrode layer 230 or the selector layer 240 may be deteriorated, but the presence of the conductive thin layer 215A may function to alleviate the nonuniformity. Therefore, the process reliability may be improved and the performance and yield of the memory device may be stably maintained by securing the thickness of the conductive thin layer 215A.

The lower electrode layer 230 may be disposed at both ends of the memory cell MC, that is, at the bottom and top of the memory cell MC, respectively, and may function to transfer voltage or current required for an operation of the memory cell MC. The lower electrode layer 230 may be electrically connected to a variable resistance layer (not shown) or the selector layer 240. The lower electrode layer 230 may include at least one selected from the group including C, CN, SiO₂, Si₃N₄, HfO₂, Al₂O₃, TiO₂, Ti, TiN, TiAlN, W, WN, Ta, TaN, Ru, RuO₂, Mo, MoN, Ir, and Pt.

The lower electrode layer 230 may preferably include at least one selected from the group including C, CN, SiO₂, Si₃N₄, HfO₂, Al₂O₃, and TiO₂. By including these materials, the lower electrode layer 230 may provide high thermal and chemical stabilities. Oxide-based materials, such as HfO₂, Al₂O₃, and TiO₂, may have a high dielectric constant and excellent heat resistance, and may maintain stability even in a high-temperature process. This may contribute to improving the reliability of the memory device.

Also, the lower electrode layer 230 may have excellent electrical characteristics. For example, carbon (C) and carbon nitride (CN) may improve electron mobility while providing low resistance characteristics, and HfO₂ and Al₂O₃ may have dielectric characteristics and function to reduce the leakage current. These characteristics may be advantageous for maintaining the operational stability of the memory cell MC.

Furthermore, the lower electrode layer 230 may improve the interface characteristics with the variable resistance layer or the selector layer 240. Since the lower electrode layer 230 is electrically connected to the variable resistance layer or the selector layer 240, the electrical characteristics at the interface may become an important factor. Materials such as SiO₂, Si₃N₄, HfO₂ and the like may suppress oxidation reactions at the interface and optimize the interface resistance between the electrode and the variable resistance layer to provide more uniform conduction characteristics.

Finally, the lower electrode layer 230 may also be advantageous in terms of process suitability and improved reliability of the device. TiO₂, Al₂O₃, and HfO₂ may be materials widely used in the semiconductor fabrication process. With a high compatibility with the existing processes and excellent plasma damage resistance, they may be able to secure long-term durability. Therefore, by applying the lower electrode layer 230 including these materials, the performance and fabrication stability of the memory device may be improved at the same time.

Referring to FIG. 2E, by performing a chemical mechanical polishing (CMP) process on the lower electrode layer 230, the micro-dishing phenomenon may be controlled not to occur over the oxide gap-fill layer 220. As a result, the surface of the lower electrode layer 230 may be planarized to form a lower electrode layer 230A having a planarized surface with a predetermined thickness T₆. Micro-dishing may refer to a fine uneven structure that is formed when a polishing pad and slurry excessively polish the oxide gap-fill layer 220, which is relatively soft, during the CMP process, and this may serve as one of the main causes that may decrease the reliability of the device in the subsequent process.

In general, the chemical mechanical polishing (CMP) process is used to planarize a specific layer by employing a slurry that reacts chemically while being mechanically abraded by a polishing pad. However, when the materials involved—such as metals and oxides—exhibit differing mechanical hardness and chemical reactivity, significant disparities in polishing rates may arise. This mismatch can lead to micro-dishing, particularly when the structure comprises both the lower electrode layer 230 and the oxide gap-fill layer 220. Since the oxide gap-fill layer 220 is mechanically softer than the surrounding metal, it tends to be removed more rapidly during CMP, increasing the likelihood of dishing. Consequently, the surface may become non-uniform, adversely affecting the thickness uniformity of a layer deposited thereafter. Such variations can introduce discrepancies in device performance by altering its electrical characteristics.

To mitigate or prevent these effects, the CMP process for the lower electrode layer 230 is precisely controlled. This involves optimizing the selection of the polishing slurry and pad to achieve a balanced removal rate between the oxide gap-fill layer 220 and the lower electrode layer 230. Specialized slurries or adjustments to the pad hardness can be employed to minimize disparities in the polishing rates of metals and oxides. Additionally, the CMP process is carefully terminated at the optimal point to prevent over-polishing and avoid excessive erosion of the oxide gap-fill layer 220. To achieve this, real-time process monitoring techniques—such as end point detection (EPD)—is applied to accurately halt polishing at the desired thickness. Moreover, a pre-treatment step may be introduced to optimize the surface condition of the oxide gap-fill layer 220 prior to forming the lower electrode layer 230. For instance, by improving the surface topology through a pre-CMP process, a more uniform polishing rate can be realized during subsequent CMP steps.

When the structure illustrated in FIG. 2E is formed through the process optimization, micro-dishing may not occur over the oxide gap-fill layer 220 even though the CMP process is performed. As a result, the planar surface between the lower electrode layer 230 and the oxide gap-fill layer 220 may be maintained, and a uniform deposition thickness may be secured in the subsequent process, thereby improving the performance and reliability of the memory cell. In particular, the formation of the uniform surface may improve the bonding characteristics with the variable resistance layer or the selector layer 240 and may minimize the variation in the electrical characteristics that may occur due to an ununiform thickness.

For this reason, it may be said that preventing the micro-dishing in the CMP process of the lower electrode layer 230 may act as a key processing element for securing the performance and reliability of the entire device beyond simply maintaining the planar surface.

Referring to FIG. 2F, the selector layer 240, the first intermediate electrode layer 250, and the second intermediate electrode layer 260 may be formed over the planarized lower electrode layer 230A in the recited order. Also, although not illustrated, a variable resistance layer may be further formed in the upper or lower portion of the selector layer 240, and a high-density layer may be deposited on the sidewall of the variable resistance layer to form a spacer. The spacer may include a high-density layer having an excellent etching selectivity, for example, a material selected from the group including silicon nitride, tantalum nitride, tungsten, titanium nitride, aluminum oxide, hafnium oxide, and platinum.

The selector layer 240 may have a function of preventing a current leakage that may occur between the memory cells MC that share the first conductive line pattern 210 or the second conductive line pattern (not shown) while controlling the access to the variable resistance layer. To this end, the selector layer 240 may have threshold switching characteristics of blocking the current or holding the current to hardly flow when the level of the voltage supplied to the upper and lower ends of the selector layer 240 is below a predetermined threshold voltage, and then letting the current to flow rapidly at a voltage level which is equal to or higher than the threshold voltage. The selector layer 240 may be turned on at a voltage level which is equal to or higher than the threshold voltage and turned off at a voltage level lower than the threshold voltage.

The selector layer 240 may include an OTS (Ovonic Threshold Switching) material such as a diode, a chalcogenide-based material and the like, an MIEC (Mixed Ionic Electronic Conducting) material such as a metal-containing chalcogenide-based material and the like, an MIT (Metal Insulator Transition) material such as NbO₂, VO₂ and the like, or a tunneling dielectric material having a relatively wide band gap such as SiO₂, Al₂O₃ and the like.

Also, the selector layer 240 may include a dielectric material that is doped with a dopant. The dielectric material may include a silicon-containing dielectric material such as silicon oxide, silicon nitride, silicon oxynitride and the like, a dielectric metal oxide, a dielectric metal nitride, or a combination thereof. The dopant may function to capture a conductive carrier moving in the dielectric material or creating a trap site that provides a path for the captured conductive carrier to move again. To form the trap site, diverse elements that may generate energy potentials capable of accommodating conductive carriers in the dielectric material may be used as dopants. For example, the dielectric material may contain silicon and the dopant may include a metal having a different valence from that of silicon, such as gallium (Ga), boron (B), indium (In), phosphorus (P), arsenic (As), antimony (Sb), germanium (Ge), carbon (C), tungsten (W), or a combination thereof. Also, as another example, the dielectric material may contain a metal and the dopant may include a metal having a different valence from that of the metal, such as silicon. For example, the selector layer 240 may include silicon dioxide (SiO₂) that is doped with arsenic (As) or germanium (Ge). When a voltage which is equal to or higher than the threshold voltage is applied to the selector layer 240 including the dielectric material that is doped with the dopant, an on-state in which the current flows through the selector layer 240 may be realized as the conductive carriers move through the trap site, and when the voltage applied to the selector layer 240 is decreased to a level which is lower than the threshold voltage, an off-state in which the current does not flow because the conductive carrier does not move may be realized.

The variable resistance layer may be a portion that functions to store data in the memory cell MC. To this end, the variable resistance layer may have the variable resistance characteristics of switching between different resistance states according to the applied voltage. The variable resistance layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetoresistive Random Access Memory (MRAM) and the like, for example, metal oxides such as transition metal oxides, perovskite-based materials and the like, phase-change materials such as chalcogenide-based materials and the like, ferroelectric materials, ferromagnetic materials, and the like. For example, the variable resistance layer may include a magnetic tunnel junction structure capable of storing data by switching between different resistance states according to the variation of the magnetization direction. When the variable resistance layer has a high resistance state, the memory cell MC may be said to store, for example, data ‘0’, and when the variable resistance layer 160 has a low resistance state, the memory cell MC may be said to store, for example, data ‘1’.

The first intermediate electrode layer 250 and the second intermediate electrode layer 260 may function to electrically connect the selector layer 240 and the variable resistance layer to each other while physically separating them from each other. The lower electrode layer 230, the first intermediate electrode layer 250, and the second intermediate electrode layer 260 may be formed of a same material, or may be formed of different materials. The lower electrode layer 230, the first intermediate electrode layer 250, and the second intermediate electrode layer 260 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or combinations thereof. Also, the lower electrode layer 230, the first intermediate electrode layer 250, and the second intermediate electrode layer 260 may include carbon electrodes. The lower electrode layer 230, the first intermediate electrode layer 250, and the second intermediate electrode layer 260 may have the same thickness or different thicknesses.

Also, the first intermediate electrode layer 250 may include at least one selected from the group including titanium nitride (TiN), tantalum nitride (TaN), ruthenium (Ru), molybdenum (Mo), tungsten (W), and platinum (Pt), and the second intermediate electrode layer 260 may include at least one selected from the group including ruthenium (Ru), tantalum (Ta), titanium nitride (TiN), copper (Cu), and tungsten (W). The materials of the first intermediate electrode layer 250 and the second intermediate electrode layer 260 may be selected differently according to their functions and characteristics required respectively.

The first intermediate electrode layer 250 may serve to stably supply the current and optimize the electrical contact to the underlying structure. Therefore, a material having a low resistance and excellent conductivity may be suitable. Metal-based materials such as titanium nitride (TiN), tantalum nitride (TaN), ruthenium (Ru), molybdenum (Mo), tungsten (W), and platinum (Pt) may provide a high electrical conductivity, which may contribute to maintaining the operational stability of the memory device. In particular, titanium nitride (TiN) and tantalum nitride (TaN) may have an excellent durability while having a low resistance and may suppress the chemical reaction with another layer by serving as a diffusion barrier. Ruthenium (Ru) and platinum (Pt) may be noble metal-based materials having a high oxidation resistance and they help maintain a stable bonding between the electrodes. Molybdenum (Mo) and tungsten (W) may provide excellent heat resistance and maintain physical and chemical stabilities even in a high-temperature environment, so they may be appropriate for memory devices whose reliability is important.

The second intermediate electrode layer 260 may be a layer that mainly contacts the variable resistance layer or the selector layer 240 directly. As for the second intermediate electrode layer 260, it is important to optimize the interface characteristics and stably maintain the characteristics of the device. Therefore, materials such as ruthenium (Ru), tantalum (Ta), titanium nitride (TiN), copper (Cu), and tungsten (W) may be preferably used for the second intermediate electrode layer 260. Since ruthenium (Ru) may have a high conductivity and a high oxidation resistance, it may be advantageous for forming uniform contact at the interface with the variable resistance layer. Tantalum (Ta) and titanium nitride (TiN) may serve as diffusion barriers to prevent a chemical reaction with the variable resistance layer and ensure long-term reliability. Since copper (Cu) has a low resistance, it may contribute to increasing the signal transfer rate and decreasing power consumption. Tungsten (W) may have a high melting point and durability and help secure the mechanical stability of the electrode layer.

Because the first intermediate electrode layer 250 and the second intermediate electrode layer 260 are each composed of materials specifically optimized for their respective functions—as detailed above—the overall performance of the memory device can be maximized while ensuring sustained long-term reliability.

During the cell patterning process, a cell pattern corresponding to the ‘C region’ may be formed, which reflects key attributes influencing the formation of the selector layer 240. In contrast to the ‘B region’ shown in FIG. 1G—a comparative example—the ‘C region’ pattern may result in a selector structure with improved thickness uniformity.

In the ‘B region’ of the comparative example described in FIG. 1G, when the lower electrode layer 130B remains thick after the CMP process, the micro-dishing phenomenon may occur continuously, and the subsequent process of forming the selector layer 140, scattering of arsenic (As) ions may become serious during the deposition of silicon oxide and the arsenic (As) ion implantation, which may result in a problem in which the upper portion of the selector layer 140 becomes nonuniformly thick. This may lead to the formation of an irregular cell with a thick edge of the selector pattern after a cell patterning process, which may be a factor that deteriorates the uniformity of the electrical characteristics.

On the other hand, since the selector layer 240 is formed in the ‘C region’ while the thickness of the lower electrode layer 230A is maintained uniformly in accordance with the embodiment of the present disclosure, the problem shown in FIG. 1G may be prevented. The uniform lower electrode layer 230A may induce the selector layer 240 to have a predetermined thickness in the subsequent process, which is important in securing the uniformity of the electrical characteristics. In particular, when the thickness of the selector layer 240 is constant, the variation of the threshold voltage may be minimized and the electrical characteristics between cells may be maintained uniformly.

Also, the formation of the uniform selector layer 240 may contribute to increasing the reliability of the device and improving the reproducibility in the repetitive processes. This may be an important factor in the mass production process of semiconductor devices and may help lower the defect rate and secure the stability of the fabrication process by forming a uniform cell pattern. Therefore, according to this embodiment of the present disclosure, by sufficiently securing the thickness of the lower electrode layer 230A and maintaining the thickness of the lower electrode layer 230A at a uniform level, the selector pattern may be induced to have a predetermined thickness in the cell pattern of the patterned ‘C region’. As a result, a semiconductor device with high reliability may be realized.

Sufficiently securing the thickness of the lower electrode layer 230A disposed in the upper portion of the first conductive line pattern 210 may be a key function in forming the selector layer 240. By securing the lower electrode layer 230A with an appropriate thickness in the upper portion of the first conductive line pattern 210, the phenomenon of the material included in the first conductive line pattern 210 being scattered during the arsenic (As) ion implantation process when the selector layer 240 is formed may be effectively controlled.

Controlling the scattering of arsenic (As) ions is essential to prevent undesirable interactions with metal components, which could lead to interface deformation or contamination. When the scattering is controlled, the arsenic (As) ions may be prevented from reacting with the metal and causing unexpected interface deformation or contamination. This may have a great influence on the electrical characteristics of the selector layer 240. When the scattering is not controlled, the characteristics of the selector layer 240 may be deteriorated, or an nonuniform selector layer may be highly likely to be formed. The uniformity of the selector layer 240 may have a significant influence on the performance of the memory cell, and the nonuniform selector layer may cause diverse problems such as unstable electrical characteristics, increased leakage current, and resistance changes.

Therefore, when the thickness of the lower electrode layer 230A is sufficiently secured, the selector layer may be formed more uniformly when an ion implantation process is performed during the process of forming the selector layer 240. This uniform selector layer 240 may optimize the performance of the memory cell and minimize the difference in characteristics between cells. As a result, the overall performance of the SC-MRAM may be improved, which may contribute to increasing the yield of the fabrication process.

Furthermore, maintaining uniform thickness and material characteristics of the selector layer 240 enhances process reliability and contributes to the stable operation of the entire memory cell. This may also improve the long-term reliability of the SC-MRAM device. Ultimately, such improvements support the fabrication of high-performance memory devices and serve as significant factors for improving both productivity and product quality.

Through the above process, the semiconductor device in accordance with the embodiment of the present disclosure may be formed. Referring back to FIG. 2F, according to the embodiment of the present disclosure, the semiconductor device may be fabricated to include the first conductive line pattern 210 over the substrate 200, the conductive thin layer 215A disposed over the first conductive line pattern 210, the oxide gap-fill layer 220 disposed between the first conductive line patterns 210, the lower electrode layer 230A, the selector layer 240, the first intermediate electrode layer 250, and the second intermediate electrode layer 260.

The semiconductor device and the method for fabricating the same described above may provide innovative technological advantages that may contribute to improving the performance of a memory device, ensuring process stability, and increasing the reliability of the device. This may be suitable for fabricating a high-performance semiconductor memory device, such as an SC-MRAM, and may ensure a high yield and performance in the commercial production.

In the semiconductor device in accordance with the embodiment of the present disclosure, a conductive thin layer 215A having a sufficient thickness may be formed in the upper portion of the first conductive line pattern 210, and the uniform physical and electrical structure may be stabilized through the oxide gap-fill layer 220. This may prevent the problem of forming nonuniform cells or abnormal selector layers that may occur during the formation of the selector layer 240. The uniform thickness and electrical characteristics of the selector layer 240 may be important factors for improving the performance and production yield of the SC-MRAM.

According to the embodiment of the present disclosure, it is possible to minimize the formation of pores or defects that may occur in the subsequent process by forming the conductive thin layer 215A sufficiently thick and disposing the oxide gap-fill layer 220 over the conductive thin layer 215A. The stability of this process may contribute to improving the reliability of the device, in particular, it may improve the durability and chemical resistance in a high-temperature environment. This may ensure the long-term stability of the memory device.

When the thickness of the conductive thin layer 215A is sufficiently secured, the reaction between the metal and arsenic (As) may be prevented during the arsenic (As) ion implantation when the selector layer 240 is formed, and deterioration of the electrical characteristics of the selector layer 240 may be prevented by controlling the scattering. As a result, the performance of the selector layer 240 may be stably maintained, and the uniformity of the cell pattern may be secured.

For an SC-MRAM, maintaining uniform characteristics for both the selector layer 240 and the lower electrode layer 230A is important. According to this embodiment of the present disclosure, a high-performance SC-MRAM may be realized by preventing the deterioration phenomenon and electrical imbalance that may occur when the selector layer 240 is formed. Also, the uniform thickness and stability of the selector layer 240 may have a significant influence on the response rate and reliability of the memory device and may improve the data read/write speed and the power consumption efficiency.

Through the stability of the oxide gap-fill layer 220 and the protective function of the conductive thin layer 215A, the device may be able to maintain the stability even in a high-temperature environment. This may make it possible to minimize the deterioration that may occur when semiconductor devices are used in a high-temperature and high-voltage environment for a long time or performance deterioration.

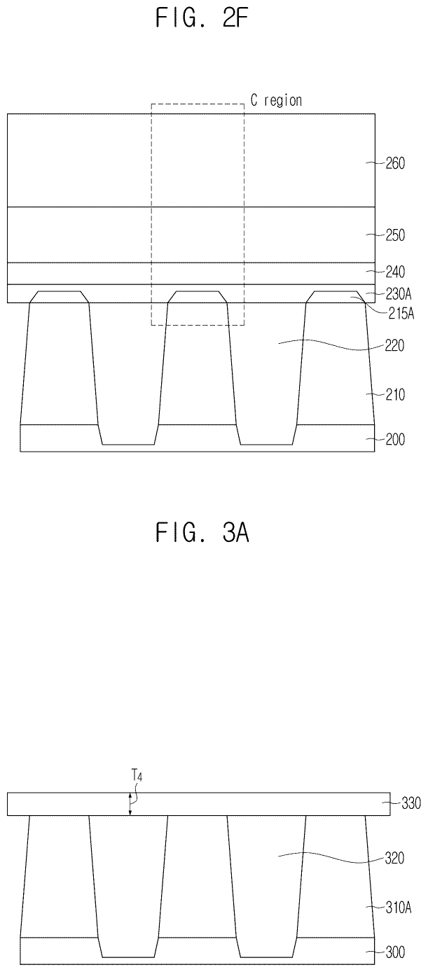

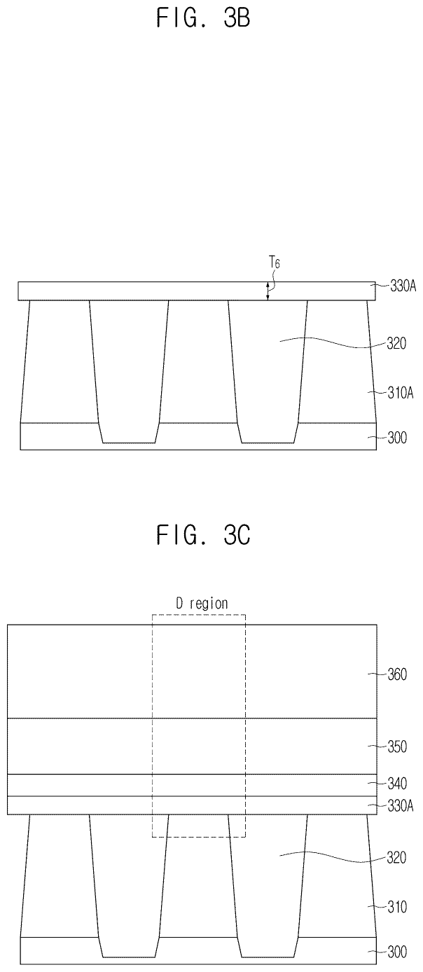

FIGS. 3A to 3C illustrate a semiconductor device and a method for fabricating the same in accordance with another embodiment of the present disclosure.

Referring to FIGS. 3A and 3B, a pre-cleaning process may be performed on a structure which is identical to the process result of FIG. 2C, that is, a structure in which a first conductive line pattern 310A over a substrate 300, an oxide gap-fill layer 320 formed between the first conductive line patterns 310A, and a lower electrode layer 330 having a thickness of T₄ are formed. The pre-cleaning process may use hydrogen peroxide (H₂O₂). In addition to hydrogen peroxide (H₂O₂), other suitable pre-cleaning agents such as dilute hydrofluoric acid (HF), sulfuric acid-hydrogen peroxide mixture (SPM), or ozonated water may also be used depending on the material characteristics and desired surface conditions. In this case, when the lower electrode layer 330 in the upper portion of the first conductive line pattern 310A is etched, the step height may be removed and thus planarization may be achieved without performing a separate CMP process. When the planarization is not achieved, a planarized lower electrode layer 330A having an appropriate thickness or more T₆ may be obtained by applying a CMP process on the lower electrode layer 330, which is a method currently used.

Hydrogen peroxide is a strong oxidizing agent, and has the characteristic of oxidizing and removing organic substances, fine impurities, oxides and the like that exist on the surface. This process may be used especially before or after the formation of the lower electrode layer 330 to keep the surface clean and contribute to improving the quality of the device. One of the major functions of hydrogen peroxide may be to effectively remove impurities from the surface of a metal, which may help increase the adhesion between the electrode and other layers in the subsequent process and improve the planarization performance of the electrode.

Hydrogen peroxide may have the characteristics of oxidizing and removing organic substances or impurities that exist on the surface of the metal and activating the surface of an oxide. Activating the surface in this way may improve the bonding between the electrode layer and the substrate, and may prevent the problem of the unstable interface that may occur between the electrode and the substrate. Hence, hydrogen peroxide enhances interfacial stability by both cleaning and activating the metal and oxide surfaces to promote stronger bonding between the electrode and the substrate. Also, the pre-treatment using hydrogen peroxide may also contribute to improving the thickness or quality of the oxide, thereby preventing the formation of a nonuniform interface that may occur in the subsequent process. For example, when the surface of the lower electrode layer 330 is etched following hydrogen peroxide pre-treatment, residual step height may be naturally minimized, thereby achieving a degree of planarization. If this planarization is inadequate, a subsequent CMP (chemical mechanical polishing) process may be employed to further planarize the surface and ensure that the lower electrode layer 330A attains a uniform thickness above a required threshold. In essence, a combination of wet etching and CMP can be used complementarily to achieve an optimal surface profile for subsequent layer formation.

The pre-cleaning process using hydrogen peroxide may not only simply remove the impurities of the surface but also prevent surface contamination and enhance planarization and uniformity of the lower electrode layer 330. This result may contribute to increasing the bonding strength between the lower electrode layer 330 and the selector layer 340 in the subsequent process and improving the electrical characteristics.

Also, the hydrogen peroxide pre-treatment may play an important role in enhancing the bonding between the metal and the oxide. It may prevent an unstable interface that may occur as the metal reacts with the oxide and prevent deterioration in the electrical performance or a problem of adhesion that may occur from the unstable interface. Also, the hydrogen peroxide pre-treatment may be advantageous in that it is cost-effective compared to a general cleaning process and has a short cleaning speed or processing time. This may increase the efficiency of the fabrication process and reduce the costs while maintaining the quality of the device.

This pre-cleaning process may be performed at a temperature of approximately 25 to 80 °C for approximately 1 to 5 minutes. First, hydrogen peroxide may have different reactivities according to the temperature. At a temperature of approximately 25 °C or higher, hydrogen peroxide may more effectively remove organic substances and metal impurities on the surface and also provide appropriate reactivity for activating the surface of the oxide. On the other hand, when the temperature exceeds approximately 80 °C, the decomposition of hydrogen peroxide may progress rapidly, which may reduce the cleaning effect, and there is a possibility that unwanted deformation of the interface may occur due to the excessive oxidation reaction. Therefore, maintaining the temperature in the range of approximately 25 to 80 °C may be suitable for securing a stable cleaning process.

Also, setting the cleaning time to approximately 1 to 5 minutes may prevent unnecessary over-etching or surface damage while allowing hydrogen peroxide sufficient time to cause a surface reaction to remove impurities. When the cleaning process is performed for less than approximately 1 minute, the organic substances or oxidation impurities on the surface of the metal may not be completely removed, which may cause a decrease in the adhesion on the interface or a variation of the electrical characteristics in the subsequent process. On the contrary, when the cleaning process is performed for more than approximately 5 minutes, the metal layer may be excessively oxidized, which may hinder the thickness uniformity of the electrode layer and cause unexpected surface defects.

By selecting these optimal cleaning conditions, the surface of the lower electrode layer 330 may be effectively cleaned to maintain the planar surface and uniformity, and the interfacial bonding force with the selector layer 340 may be maximized. In particular, the formation of a uniform interface is important in stably maintaining the electrical characteristics of the cell and may contribute to maximizing the performance of the next-generation memory devices such as the SC-MRAM. Also, by setting an appropriate cleaning time and temperature, the repeatability and reliability of the process may be secured, and uniform device characteristics may be maintained even during mass production.

Referring to FIG. 3C, a selector layer 340, a first intermediate electrode layer 350, and a second intermediate electrode layer 360 may be formed over the planarized lower electrode layer 330A in the recited order. Also, although not illustrated, a variable resistance layer may be further formed in the upper or lower portion of the selector layer 340, and a high-density layer may be deposited on the sidewall of the variable resistance layer to form a spacer. The spacer may include a high-density layer with excellent etching selectivity, for example, a material selected from the group including silicon nitride, tantalum nitride, tungsten, titanium nitride, aluminum oxide, hafnium oxide, and platinum.

During the cell patterning process, a cell pattern corresponding to the ‘D region’ may be formed. The presence of a uniform lower electrode layer 330A facilitates the formation of the selector layer 340 and its associated pattern with a predetermined and consistent thickness in subsequent steps. This uniformity is crucial for maintaining stable electrical characteristics across memory cells, thereby enhancing device performance and reliability. Also, the formation of the uniform selector layer 340 and selector pattern may contribute to increasing the reliability of the device and improving the reproducibility in repetitive processes. Ensuring a sufficient thickness of the lower electrode layer 330A disposed in the upper portion of the first conductive line pattern 310 may play a key role in the formation of the selector layer 340. By securing the lower electrode layer 330A with an appropriate thickness in the upper portion of the first conductive line pattern 310, it is possible to effectively control the phenomenon in which the material included in the first conductive line pattern 310 scatters during the arsenic (As) ion implantation process when the selector layer 340 is formed.

The semiconductor device in accordance with an embodiment of the present disclosure, as illustrated in FIG. 3C, may be fabricated by the process described above. As described above the lower electrode layer 330 may be planarized without performing a separate CMP process, which is advantageous in terms of process simplification and cost reduction. Also, when sufficient planarization is not achieved by the cleaning process alone, a general CMP process may be additionally performed to secure the lower electrode layer 330A with an appropriate thickness or more, thereby forming a uniform lower electrode layer 330A. This may allow the selector layer 340 to be formed more stably, and furthermore contribute to improving the electrical characteristics and reliability of the cell.

Ensuring the thickness of the lower electrode layer 330A sufficiently may be an important factor in the process of forming the selector layer 340. When the lower electrode layer 330A of an appropriate thickness exists in the upper portion of the first conductive line pattern 310, the phenomenon of the metal element included in the first conductive line pattern 310 being scattered during the subsequent arsenic (As) ion implantation process may be effectively controlled. This may contribute to preventing interface contamination or unexpected interface deformation that may occur as the arsenic (As) ions directly react with the conductive line pattern 310, and consequently, enable the selector layer 340 to be formed uniformly.

Also, according to an embodiment of the present disclosure, a variable resistance layer may be additionally formed, and a spacer may be formed on the sidewall of the variable resistance layer to increase the precision degree of the process. The spacer may be formed by using a high-density layer having a high etching selectivity, and the spacer may be formed of a material such as silicon nitride, tantalum nitride, tungsten, titanium nitride, aluminum oxide, hafnium oxide, and platinum. The spacer may be able to prevent the electrical interference between the variable resistance layer and the peripheral structures and further improve the electrical characteristics of the cell.

As a result, according to an embodiment of the present disclosure, process simplification and cost reduction may be possible, and the electrical characteristics of the selector layer 340 may be stably maintained by forming the lower electrode layer 330A uniformly. Also, the contamination on the interface may be prevented by suppressing unnecessary scattering, and the performance and reliability of the next-generation memory devices such as an SC-MRAM may be maximized by optimizing the structures of the variable resistance layer and the spacer.

According to an embodiment of the present disclosure, the semiconductor device and the method for fabricating the same may prevent deterioration of a selector layer by sufficiently securing the thickness of the lower electrode layer that is disposed in the upper portion of the first conductive line thereby making it possible to control scattering of a material included in the first conductive line during the process of forming the selector layer.

Also, according to an embodiment of the present disclosure, the semiconductor device and the method for fabricating the same may improve the performance and production yield of a SC-MRAM by forming a selector layer of a uniform thickness thereby making it possible to secure uniform cells.

While the embodiments of the present disclosure have been described with respect to specific embodiments, it will be apparent to those skilled in the art that various changes and modifications may be made to the embodiments without departing from the technical concepts and scope of the present disclosure as defined in the following claims. Furthermore, the embodiments may be combined to form additional embodiments. What is claimed is:

1. A semiconductor device comprising:
a plurality of first conductive line patterns, each having a first conductive layer being disposed thereon;
a lower electrode layer formed over the plurality of first conductive line pattern, wherein the lower electrode layer includes at least one selected from a group including C, CN, SiO₂, Si₃N₄, HfO₂, Al₂O₃, TiO₂, Ti, TiN, TiAlN, W, WN, Ta, TaN, Ru, RuO₂, Mo, MoN, Ir, and Pt; and
a selector layer formed over the lower electrode layer,
wherein the first conductive layer and the lower electrode layer are formed of a same material.

2. The semiconductor device of claim 1, wherein the first conductive layer has a thickness of 10 nm to 30 nm.

3. The semiconductor device of claim 1, wherein the lower electrode layer includes at least one selected from a group including C, CN, SiO₂, Si₃N₄, HfO₂, Al₂O₃, and TiO₂.

4. The semiconductor device of claim 1, further comprising:
a variable resistance layer disposed in an upper or lower portion of the selector layer.

5. The semiconductor device of claim 4, wherein a spacer including a material selected from a group including silicon nitride, tantalum nitride, tungsten, titanium nitride, aluminum oxide, hafnium oxide, and platinum is formed on a sidewall of the variable resistance layer.

6. The semiconductor device of claim 1, wherein each of the first conductive line pattern includes tungsten.

7. The semiconductor device of claim 1, further comprising:
a first intermediate electrode layer and a second intermediate electrode layer disposed in an upper portion of the selector layer.

8. The semiconductor device of claim 7, wherein the first intermediate electrode layer includes
at least one selected from a group including TiN, TaN, Ru, Mo, W, and Pt, and
the second intermediate electrode layer includes at least one selected from a group including Ru, Ta, TiN, Cu, and W.

9. The semiconductor device of claim 1, wherein an oxide gap-fill layer is formed between the first conductive line patterns.

10. The semiconductor device of claim 9, wherein the oxide gap-fill layer includes at least one selected from a group including silicon oxide, aluminum oxide, zirconium oxide, hafnium oxide, tantalum oxide, magnesium oxide, and yttrium oxide.

11. A method for fabricating a semiconductor device, the method comprising:
forming a conductive thin layer over a first conductive line;
forming a plurality of first conductive line patterns by patterning the first conductive line over which the conductive thin layer is formed;
forming an oxide gap-fill layer between the first conductive line patterns;
forming a lower electrode layer over the first conductive line patterns and the oxide gap-fill layer; and
planarizing an upper surface of the lower electrode layer,
wherein the conductive thin layer and the lower electrode layer are formed of a same material.

12. The method of claim 11, wherein the lower electrode layer includes at least one selected from a group including C, CN, SiO₂, Si₃N₄, HfO₂, Al₂O₃, TiO₂, Ti, TiN, TiAlN, W, WN, Ta, TaN, Ru, RuO₂, Mo, MoN, Ir, and Pt.

13. The method of claim 12, wherein the lower electrode layer includes at least one selected from a group including C, CN, SiO₂, Si₃N₄, HfO₂, Al₂O₃, and TiO₂.

14. The method of claim 11, wherein the conductive thin layer is formed to have a thickness which is equal to or greater than a step height between the first conductive line patterns and the oxide gap-fill layer.

15. The method of claim 11, further comprising:
forming a selector layer over the lower electrode layer; and
forming a variable resistance layer over the selector layer.

16. The method of claim 15, further comprising:
forming an intermediate electrode layer between the selector layer and the variable resistance layer after the selector layer and the variable resistance layer are formed.

17. The method of claim 16, wherein the intermediate electrode layer includes a first intermediate electrode layer and a second intermediate electrode layer, and
the first intermediate electrode layer includes at least one selected from a group including TiN, TaN, Ru, Mo, W, and Pt, and
the second intermediate electrode layer includes at least one selected from a group including Ru, Ta, TiN, Cu, and W.

18. The method of claim 15, further comprising:
forming a spacer by depositing a material selected from a group including silicon nitride, tantalum nitride, tungsten, titanium nitride, aluminum oxide, hafnium oxide, and platinum on a sidewall of the variable resistance layer.

19. The method of claim 11, wherein the oxide gap-fill layer includes at least one selected from a group including silicon oxide, aluminum oxide, zirconium oxide, hafnium oxide, tantalum oxide, magnesium oxide, and yttrium oxide.

20. The method of claim 11, wherein the first conductive line includes tungsten.

21. The method of claim 11, further comprising:
cleaning an upper surface of the lower electrode layer by pre-treating the upper surface of the lower electrode layer with hydrogen peroxide before planarizing the upper surface of the lower electrode layer.

22. The method of claim 21, wherein cleaning the upper surface of the lower electrode layer by pre-treating the upper surface of the lower electrode layer with hydrogen peroxide before the planarizing of the upper surface of the lower electrode layer is performed at a temperature of 25 to 80 °C for 1 to 5 minutes.

23. A semiconductor device, comprising:
a plurality of first conductive line patterns disposed over a substrate;
an oxide gap-fill layer between the first conductive line patterns;
a conductive thin layer having a thickness of 10 nm to 30 nm and being disposed on the first conductive line patterns;
a lower electrode layer formed over the first conductive line patterns and the oxide gap-fill layer; and
a selector layer formed over the lower electrode layer,
wherein the conductive thin layer and the lower electrode layer are formed of a same material.
